(19) United States
(12) Patent Application Publication
(10) Pub. No.: US 2015/0194936 A1
(43) Pub. Date: Jul. 9, 2015

(54) POWER AMPLIFIER ENVELOPE TRACKING

(71) Applicant: QUALCOMM Incorporated, San Diego, CA (US)

(72) Inventors: Hakan INANOGLU, Acton, MA (US); Daniel Fred FILIPOVIC, Solana Beach, CA (US); Jifeng GENG, San Diego, CA (US); Leon T. METREAUD, Pepperell, MA (US)

(73) Assignee: QUALCOMM Incorporated, San Digeo, CA (US)

(21) Appl. No.: 14/151,757

(22) Filed: Jan. 9, 2014

(51) Int. Cl. H03F 1/02; H03F 3/21; H03F 1/32

(52) U.S. Cl. CPC H03F 1/0222; H03F 1/3247; H03F 3/21; H03F 2200/102; H03F 2200/228; H03F 2200/504; H03F 2201/3215; H03F 2201/3227; H03F 2201/3233

(57) ABSTRACT

Exemplary embodiments are related to a wireless transmitter device. A device may include a power amplifier configured to receive a supply voltage and an input signal. The device may further include switch coupled to the supply voltage and the power amplifier via an inductor and configured to couple the inductor to one of a ground voltage and the supply voltage. The device may also include a prediction engine configured to receive the input signal and convey a signal to the switch to couple the inductor to the ground voltage upon detection of an overshoot event.

### BACKGROUND

1. Field

The present invention relates generally to power amplifiers. More specifically, the present invention relates to embodiments for low-cost and efficient envelope tracking of a power amplifier input signal.

2. Background

Electronic amplifiers are used for increasing a power and/or an amplitude of various electronic signals. Most electronic amplifiers operate by using power from a power supply, and controlling an output signal to match the shape of an input signal, while providing a higher amplitude signal.

One widely used type of electronic amplifier is a power amplifier, which is a versatile device used in various applications to meet design requirements for signal conditioning, special transfer functions, analog instrumentation, and analog computation, among others. Power amplifiers are often used in wireless applications, and may employ radio-frequency (RF) amplifier designs for use in the RF range of the electromagnetic spectrum. An RF power amplifier is a type of electronic amplifier used to convert a low-power RF signal into a signal of significant power, typically for driving an antenna of a transmitter. RF power amplifiers are oftentimes used to increase the range of a wireless communication system by increasing the output power of a transmitter.

Power amplifiers, typically, do not behave in a linear manner. More particularly, power amplifier distortion may compress or may expand an output signal swing of a power amplifier. Signal detectors receiving and decoding the amplified signals typically do not operate in such a non-linear fashion. Therefore, it is usually necessary to linearize an output of a power amplifier. One approach to such linearization is digital pre-distortion (DPD). Digital pre-distortion may be calibrated and used with power amplifiers to invert power amplifier distortion characteristics by expanding compression regions and compressing expansion regions of power amplifier characteristics.

Further, as will be appreciated, in some configurations, power amplifiers may receive a supply voltage, which, ideally, should track an envelope of an input signal of the power amplifier. A need exists for enhancing the efficiency of a power amplifier system. More specifically, a need exists for embodiments related to a low-cost, efficient envelope tracking power amplifier device.

### BRIEF DESCRIPTION OF THE DRAWINGS

FIG. 1 is a plot illustrating a radio-frequency signal and an envelope tracking signal.

FIG. 2 illustrates a device including a power amplifier, in accordance with an exemplary embodiment of the present invention.

FIG. 3 illustrates a device including a power amplifier and a prediction engine, according to an exemplary embodiment of the present invention.

FIG. 4 is a circuit diagram.

FIG. 5 illustrates another device including a power amplifier, a prediction engine, and a feedback path, in accordance with an exemplary embodiment of the present invention.

FIG. 6 is a plot depicting a radio-frequency signal and an envelope tracking signal.

FIG. 7 is a flowchart depicting another method, in accordance with an exemplary embodiment of the present invention.

FIG. 8 illustrates a device including at least one transmitter including a power amplifier and a prediction engine, in accordance with an exemplary embodiment of the present invention.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

Conventional power amplifiers are generally adapted to use one or more of four control configurations. One configuration may include a battery, which is directly connected to a supply port of a power amplifier. This may be efficient at times when maximum power is needed, but at lower power levels, efficiency drops rapidly because a full battery voltage may not be necessary. Another configuration includes average power tracking, which uses a switch, coupled between a battery and a power amplifier, and an algorithm to change voltage between various power control groups. Compared to the battery direct configuration, at lower powers, average power tracking exhibits improved efficiency since a power amplifier voltage may be correspondingly decreased. Another configuration includes a super average power tracking (SAPT) that uses an algorithm to change a supply voltage per various power control groups. SAPT may also use pre-distortion and adaptiveness to adjust the supply voltage to one or more limits. Moreover, envelope tracking (ET) uses a separate chipset to track an envelope of an input signal at high speed and high precision. ET may require power amplifiers to be optimized for ET usage and also may require an ET digital to analog converter (DAC) (e.g., within a mobile station modem (MSM)).

As an input signal of a power amplifier transitions from a low to high signal level, a power amplifier may be drive into linear to saturation region, which modulates a resistance of the power amplifier from high (e.g., ˜10 ohms) to low (e.g., ˜4 ohms) values. The modulated resistance combined with an external inductor and capacitor network may cause a self generated tracking voltage at a power supply input of the power amplifier. The self tracking voltage tracks the envelope of an input signal to the power amplifier. Although, power amplifier self power tracking (SPT) is coarse tracking (i.e., it is a “lazy” tracking), the efficiency of SPT may exceed the overall efficiency of envelope tracking (ET). This is mainly because of the efficiency loss in ET mode that comes from switching within a linear amplifier. The SPT switching efficiency is much higher than ET switching within a linear amplifier stage. Further, as will be appreciated by a person having ordinary skill in the art, the tracking voltage “overshoots” when the input signal goes from high (saturation) to low (linear) region due to a resistance change in the power amplifier.

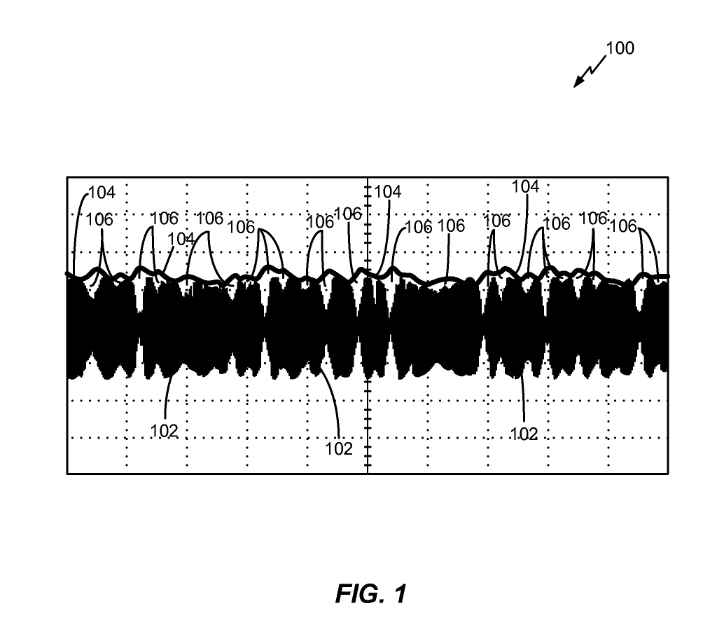

FIG. 1 is a plot 100 illustrating an RF signal 102 (i.e., an input signal of a power amplifier) and a self tracking signal 104. Plot 100 further illustrates multiple overshoot regions 106 wherein RF signal 102 received by a power amplifier is decreasing and self tracking signal 104 is “overshooting” (i.e., increasing). Stated another way, when RF signal 102 decreases, self tracking signal 104 fails to sufficiently track RF signal 102 (i.e., self tracking signal 104 overshoots RF signal 102). As will be appreciated by a person having ordinary skill in the art, overshoot regions 106 may decrease the overall efficiency of the power amplifier.

Exemplary embodiments of the present invention include a device configured to decrease envelope tracking signal overshoots by utilizing a power amplifier self tracking voltage. More specifically, according to various exemplary embodiments, a device may include a prediction engine configured to predict overshoot regions (i.e., overshoot events based on the input signal) and set a voltage at an inductor terminal, which is coupled to a supply input of a power amplifier, to a ground voltage to decrease, and possibly prevent, overshoots and, thus, increase efficiency of the device. The prediction engine may also be required to pre-distort the waveform.

According to another exemplary embodiment, a device may include a power amplifier configured to receive a supply voltage and an input signal. The device may further include a switch coupled to the supply voltage and the power amplifier via an inductor and configured to couple the inductor to one of a ground voltage and the supply voltage. In addition, the device may include a prediction engine configured to receive the input signal and convey a signal to the switch to couple the inductor to the ground voltage upon detection of an overshoot event.

According to yet another exemplary embodiment, the present invention includes methods for generating a power amplifier supply voltage while reducing overshoot events. Various embodiments of such a method may include detecting a tracking voltage overshoot event of a power amplifier and coupling an inductor coupled to a supply port of the power amplifier to a ground voltage during the tracking voltage overshoot event.

Other aspects, as well as features and advantages of various aspects, of the present invention will become apparent to those of skill in the art through consideration of the ensuing description, the accompanying drawings and the appended claims.

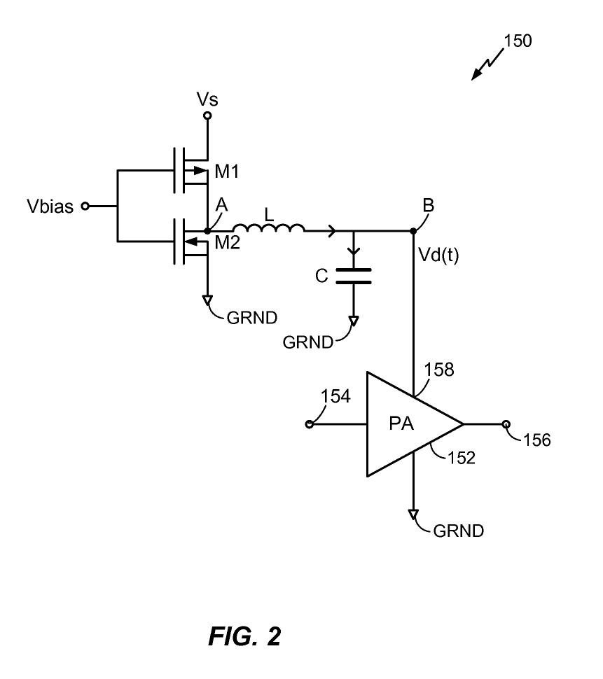

FIG. 2 illustrates a device 150, according to an exemplary embodiment of the present invention. Device 150 includes a power amplifier 152 configured to receive an input signal 154 and convey an output signal 156. Further, power amplifier 152 is configured to receive a supply voltage via a supply input 158 (e.g., a bias input).

Device 150 further includes transistors M1 and M2, an inductor L, and a capacitor C. As illustrated, transistor M1 is coupled between a voltage supply Vs and a node A, which is further coupled to one end of inductor L. A second end of inductor is coupled to a node B, which is also coupled to supply port 158 of power amplifier 152. Capacitor C is coupled between node B and a ground voltage GRND. Transistor M2 is coupled between ground voltage GRND and node A. Further, each of transistors M1 and M2 is configured to receive a bias signal Vbias. More specifically, a gate of transistor M1 is configured to receive bias signal Vbias, a drain of transistor M1 is coupled to voltage supply Vs, and a source of transistor M1 is coupled to node A. Further, a gate of transistor M2 is configured to receive bias signal Vbias, a drain of transistor M2 is coupled to ground voltage GRND, and a source of transistor M2 is coupled to node A. By way of example only, transistor M1 may comprise a p-channel field-effect transistor (PFET) and transistor M2 may comprise an n-channel field-effect transistor (NFET).

By way of example, during one state of operation, bias signal Vbias may cause transistor M1 to turn “on” (i.e., operate in a conductive state) and transistor M2 to turn “off” (i.e., operate in a non-conductive state) and, therefore, couple inductor L to voltage supply Vs via node A. During another state of operation, bias signal Vbias may cause transistor M1 to turn “off” (i.e., operate in a non-conductive state) and transistor M2 to turn “on” (i.e., operate in a conductive state) and, therefore, couple inductor L to ground voltage GRND via node A. As described more fully below, bias signal Vbias may be conveyed by a prediction engine.

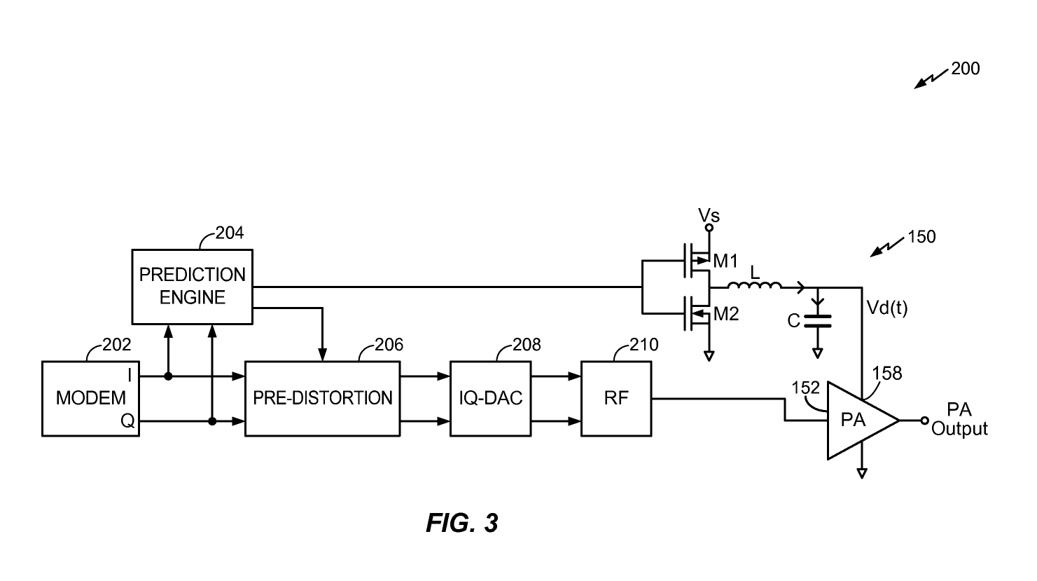

FIG. 3 depicts a device 200, in accordance with an exemplary embodiment of the present invention. Device 200 includes a modem 202, a prediction engine 204, a pre-distortion unit 206, an in-phase and quadrature digital-to-analog converter (IQ-DAC) 208, and radio-frequency (RF) circuitry 210. RF circuitry 210 may include, for example, circuitry (e.g., a mixer) for up-converting a baseband signal to RF. In addition, device 200 may include device 150 (see FIG. 2), which includes transistors M1 and M2, inductor L, capacitor C, and power amplifier 152. As illustrated in FIG. 3, an output of modem 202 is coupled to each of prediction engine 204 and pre-distortion unit 206. Prediction engine 204 is further coupled to pre-distortion unit 206 and the gates of transistors M1 and M2. IQ-DAC 208 is coupled between pre-distortion unit 206 and RF circuitry 210, which is further coupled to an input of power amplifier 102.

According to an exemplary embodiment of the present invention, prediction engine 204 may be configured to receive in-phase (I) and quadrature (Q) outputs from modem 202 and, based on a model of power amplifier 152, predict an amount of distortion to be applied via pre-distortion unit 206. Accordingly, prediction engine 204 may convey a signal to pre-distortion unit 206 that may be used to pre-distort the I and Q signals received at pre-distortion unit 206.

Pre-distortion unit 206 may process in-phase and quadrature components to produce pre-distorted I and Q components, which may be conveyed to IQ-DAC 208. In this exemplary embodiment, pre-distortion unit 206 may be configured to pre-distort the I and Q components based on a power amplifier model (i.e., prior characterization of power amplifier 152). Further, IQ-DAC 208 may convert digital I and Q signal to analog I and Q signals and convey the analog I and Q signals to RF circuitry 210. RF circuitry 210 may be configured to process the analog I and Q signals (e.g., up-convert) and convey an input signal to an input of power amplifier 152.

Further, prediction engine 204, in response to receiving and based on the I and Q signals, may detect likely overshoot events. Stated another way, prediction engine 204 may be configured to predict a tracking voltage based on the I and Q signals and estimate overshoot regions of the tracking voltage. According to one exemplary embodiment, prediction engine 204 may be configured to predict an overshoot event if a voltage level of an input signal to the power amplifier 152 is less than a threshold level.

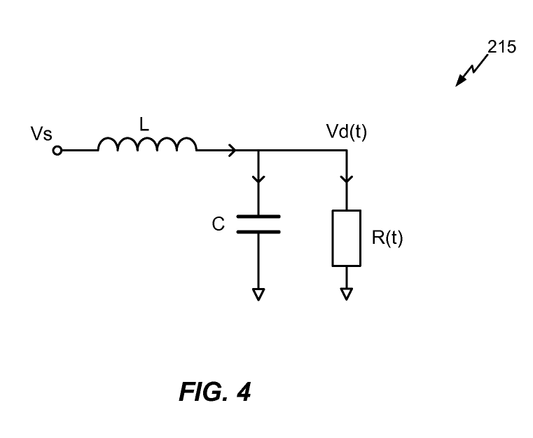

Prediction engine 204 may be configured to predict a tracking voltage based on a circuit diagram 215 illustrated in FIG. 4 and equations (1)-(9) provided below.

$$\begin{matrix}{i}_{c} ( t ) = C \frac{d {v}_{d} ( t )}{d t} ; & ( 1 ) \\ {i}_{R} ( t ) = \frac{{v}_{d} ( t )}{R ( t )} ; & ( 2 ) \\ {v}_{s} - {v}_{d} ( t ) = L \frac{d {i}_{L} ( t )}{d t} ; & ( 3 ) \\ {i}_{c} ( t ) + {i}_{R} ( t ) = {i}_{L} ( t ) ; & ( 4 ) \\ C \frac{d {v}_{d}}{d t} + \frac{{v}_{d}}{R ( t )} = \frac{1}{L} \int ( {v}_{s} - {v}_{d} ) d t ; & ( 5 ) \\ LC \frac{{d}^{2} {v}_{d}}{d {t}^{2}} + \frac{LR ( t )}{{R}^{2} ( t )} \frac{d {v}_{d}}{d t} - \frac{1}{{R}^{2} ( t )} \frac{d R}{d t} {v}_{d} + {v}_{d} = {v}_{s} ; & ( 6 )\end{matrix}$$

wherein substituting equations (1)-(3) into equation (4) provides equation (5), which may be rearranged to provide equation (6). Further, the finite difference formula for the first and second order derivatives can be written as equations (7) and (8) below. In addition, substituting equations (7) and (8) into equation (6) may provide equation (9).

$$\begin{matrix}{f}^{′} ( t ) = \frac{f ( {t}_{n + 1} ) - f ( {t}_{n - 1} )}{2 Δ t} ; & ( 7 ) \\ {f}^{″} ( t ) = \frac{f ( {t}_{n + 1} ) - 2 f ( {t}_{n} ) + f ( {t}_{n - 1} )}{Δ {t}^{2}} ; & ( 8 ) \\ \{ \frac{LC}{Δ {t}^{2}} + \frac{L}{2 R ( t ) Δ t} \} {v}_{d} ( {t}_{n + 1} ) = {v}_{s} ( {t}_{n} ) + \{ \begin{matrix}\frac{2 LC}{Δ {t}^{2}} + \frac{L}{2 {R}^{2} ( {t}_{n} ) Δ t} R ( {t}_{n + 1} ) - \\ \frac{L}{2 {R}^{2} ( {t}_{n} ) Δ t} R ( {t}_{n - 1} ) - 1\end{matrix} \} {v}_{d} ( {t}_{n} ) + \{ \frac{L}{2 R ( {t}_{n} ) Δ t} - \frac{LC}{Δ {t}^{2}} \} {v}_{d} ( {t}_{n - 1} ) ; & ( 9 )\end{matrix}$$

It is noted that equation (9) can be used to predict a tracking voltage and estimate the overshoot regions of the tracking voltage as it accurately models the PA resistance changes of a power amplifier. The resistance changes in time may be predicted from the baseband complex signal in advance so that it can be utilized in equation (9) to predict the overshoot regions. The baseband signal levels can be partitioned into two groups: samples that drives the power amplifier into saturation and the samples that keep the power amplifier in linear region. After the portioning, the resistance LUT can be generated based on the complex base band signal levels. After applying the correct resistance values in equation (9) and comparing the predicted envelope signal vd(t) with respect to the one that assumes constant R, the overshoot regions and the prediction voltage may be estimated.

In response to a predicted overshoot event, prediction engine 204 may be configured to convey a signal to the gates of transistor M1 and transistor M2 for configuring transistors to enable inductor L to be coupled between ground voltage GRND and the supply input of power amplifier 152. It is noted that device 200 does not require a DAC coupled in the supply input path (e.g., between prediction engine 204 and power amplifier 152). Achieving high efficiency without a DAC within the supply input path may be important for low-cost modems. Exemplary embodiments of the present invention may have an efficiency better than envelope power tracking (EPT) and close or possible better than ET for long term evolution (LTE) technology. Further, the proposed solution may be less sensitive to power amplifier reverse isolation issue that cause delay skews in ET.

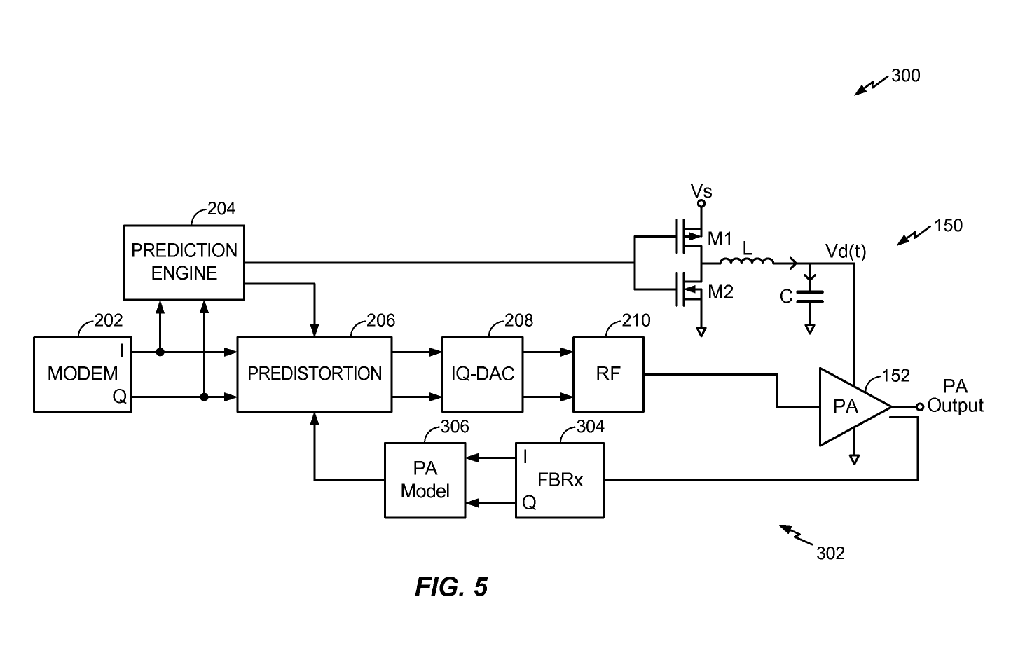

FIG. 5 illustrates another device 300, according to an exemplary embodiment of the present invention. Similar to device 200 illustrated in FIG. 3, device 300 includes modem 202, prediction engine 204, pre-distortion unit 206, IQ-DAC 208, and RF circuitry 210. In addition, device 300 may include device 150 (see FIG. 2), which includes transistors M1 and M2, inductor L, capacitor C, and power amplifier 152.

As illustrated in FIG. 5, an output of modem 202 is coupled to each of prediction engine 204 and pre-distortion unit 206. Prediction engine 204 is further coupled to pre-distortion unit 206 and the gates of transistors M1 and M2. IQ-DAC 208 is coupled between pre-distortion unit 206 and RF circuitry 210, which is further coupled to an input of power amplifier 152. Furthermore, device 300 includes a feedback loop 302 including a feedback receiver 304 and a look-up table unit 306. As illustrated, feedback receiver 304 is coupled between an output of power amplifier 102 and LUT Calc 306, which is further coupled to pre-distortion unit 206.

According to a contemplated operation of device 300, prediction engine 204 may be configured to receive in-phase (I) and quadrature (Q) outputs from modem 202 and convey a signal to pre-distortion unit 206. The signal conveyed from prediction engine 204 to pre-distortion unit 206 may be used by pre-distortion unit 206 in determining an amount of pre-distortion to apply the received I and Q signals. Pre-distortion unit 206 may process in-phase and quadrature components to produce pre-distorted I and Q components, which may be conveyed to IQ-DAC 208. Further, IQ-DAC 208 may convert digital I and Q signal to analog I and Q signals and convey the analog I and Q signals to RF circuitry 210. RF circuitry 210 may be configured to process the analog I and Q signals (e.g., up-convert) and convey an input signal to an input of power amplifier 152.

In addition, according to an exemplary embodiment of the present invention, an output of power amplifier 152 may be received at feedback receiver 304, which may then convey a signal to power amplifier model unit 306. According to one exemplary embodiment, feedback loop 302 may couple an RF signal at the output of power amplifier 152 with a directional coupler. Further, according to an exemplary embodiment, feedback receiver 304 may include circuitry for down-converting the RF signal to baseband and converting an analog baseband signal to a digital signal.

Based on the signal output from power amplifier 152, power amplifier model unit 306 models the power amplifier nonlinearity at various constant vd. This is done as part of power amplifier characterization. Therefore, according to the exemplary embodiment illustrated in FIG. 5, pre-distortion unit 206 may be configured to pre-distort the I and Q components based on a power amplifier model.

Further, similar to device 200, prediction engine 204 may detect likely overshoot events in response to receiving the I and Q signals from modem 202 Stated another way, prediction engine 204 may be configured to predict a tracking voltage base on the I and Q signals and estimate overshoot regions of the tracking voltage. Prediction engine 204 may be configured to predict a tracking voltage based on equations (1)-(3) provided above.

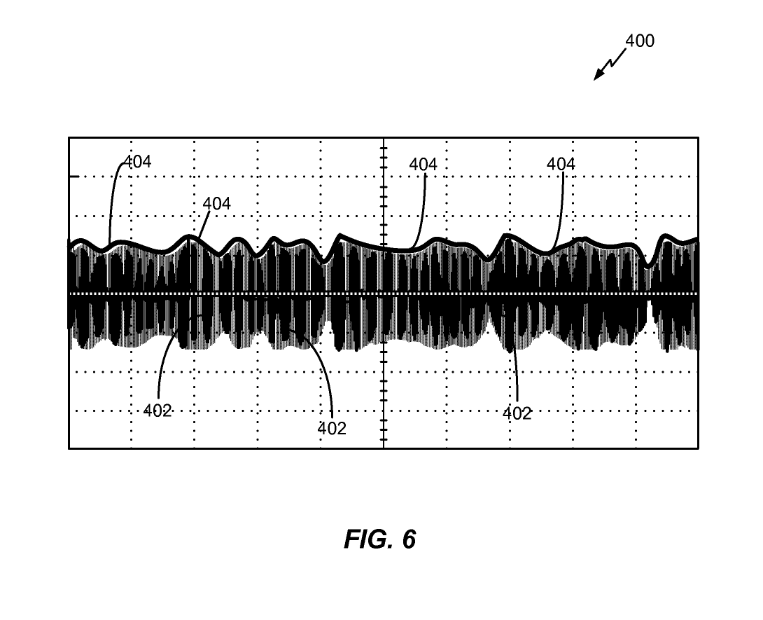

FIG. 6 is a plot 400 illustrating an RF signal 402 (i.e., an input signal of a power amplifier) and a self tracking signal 404. In comparison to plot 100 illustrated in FIG. 1, self tracking signal 404 of plot 400 more closely follows an envelope of RF signal 402 and, thus, plot 400, illustrates a decrease in overshoot regions, which results in an increase in the overall efficiency of the power amplifier.

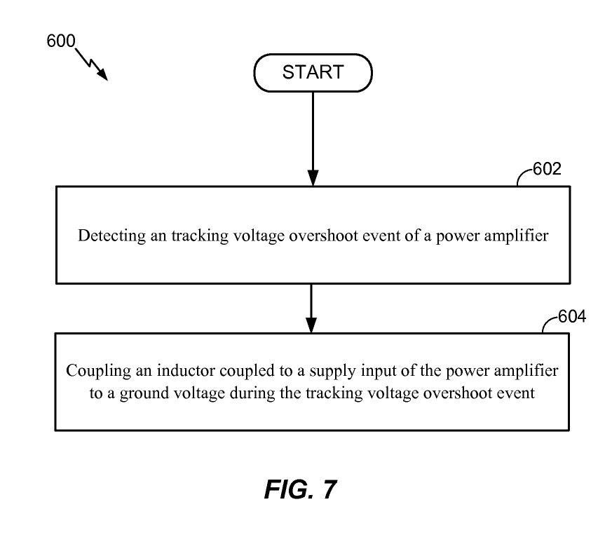

FIG. 7 is a flowchart illustrating a method 600, in accordance with one or more exemplary embodiments. Method 600 may include detecting a tracking voltage overshoot event of a power amplifier (depicted by numeral 602). In addition, method 600 may include coupling an inductor coupled to a supply port of the power amplifier to a ground voltage during the tracking voltage overshoot event (depicted by numeral 604).

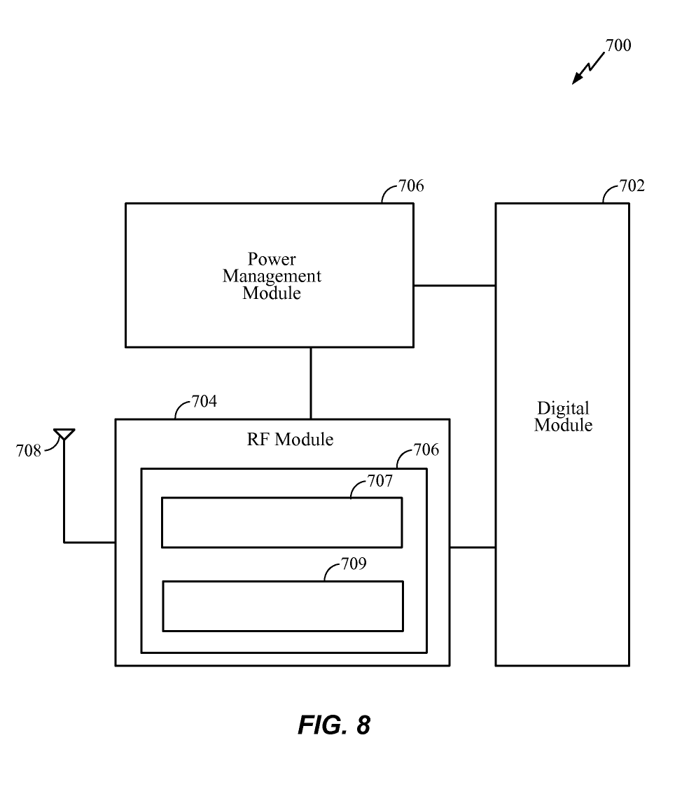

FIG. 8 is a block diagram of an electronic device 700, according to an exemplary embodiment of the present invention. According to one example, device 700 may comprise a portable electronic device, such as a mobile telephone. Device 700 may include various modules, such as a digital module 702, an RF module 704, and power management module 706. Digital module 702 may comprise memory and one or more processors. RF module 704, which may comprise RF circuitry, may include a transceiver 706 including a transmitter 707 and a receiver 709 and may be configured for bi-directional wireless communication via an antenna 708. In general, wireless communication device 700 may include any number of transmitters and any number of receivers for any number of communication systems, any number of frequency bands, and any number of antennas. According to an exemplary embodiment of the present invention, transmitter 707 may include one or more of the exemplary embodiments described below. More specifically, transmitter 707 may include one or more of devices 200 (see FIG. 3), one or more of device 300 (see FIG. 5), or any combination of devices 200 and 300.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A device, comprising:
a power amplifier configured to receive a supply voltage and an input signal;
a switch coupled to the supply voltage and the power amplifier via an inductor and configured to couple the inductor to one of a ground voltage and the supply voltage; and
a prediction engine configured to receive the input signal and convey a signal to the switch to couple the inductor to the ground voltage upon detection of a tracking voltage overshoot event.

2. The device of claim 1, further comprising a pre-distortion unit coupled to the prediction engine and configured to pre-distort the input signal based on a signal received from the prediction engine.

3. The device of claim 2, further comprising a feedback loop coupled between an output of the power amplifier and the pre-distortion unit.

4. The device of claim 3, the feedback loop comprising:
a feedback receiver coupled to the output of the power amplifier; and
a lookup table (LUT) unit coupled between the feedback receiver and the pre-distortion unit.

5. The device of claim 4, the LUT unit configured to convey a signal to the pre-distortion unit to pre-distort the I and Q components based on an output of the power amplifier.

6. The device of claim 1, the prediction engine further configured to convey a signal to a pre-distortion unit to pre-distort the I and Q components based on a model of the power amplifier.

7. The device of claim 6, wherein each of the prediction engine and the pre-distortion unit are configure to receive in-phase (I) and quadrature (Q) signals from a modem.

8. The device of claim 1, wherein the prediction engine is configured to predict the overshoot event if a voltage level of an input signal to the power amplifier is less than a threshold level.

9. The device of claim 8, the switch comprising a transistor pair comprising:
a first transistor coupled between the supply voltage and the inductor; and
a second transistor coupled between the inductor and the ground voltage.

10. A method, comprising:
detecting an tracking voltage overshoot event of a power amplifier; and
coupling an inductor coupled to a supply port of the power amplifier to a ground voltage during the tracking voltage overshoot event.

11. The method of claim 10, wherein detecting comprises detecting the overshoot event with a prediction engine configured to receive an input signal of the power amplifier.

12. The method of claim 10, wherein coupling an inductor comprises:
causing a first transistor coupled between a supply voltage and the inductor to operate in a non-conductive state; and
causing a second transistor coupled between the ground voltage and the inductor to operate in a conductive state.

13. The method of claim 10, further comprising pre-distorting an input signal of the power amplifier.

14. The method of claim 10, wherein detecting comprises detecting if a voltage level of an input signal of the power amplifier is less than a threshold level.

15. The method of claim 10, wherein detecting an overshoot event comprises detecting when a voltage level of an input signal of the power amplifier is less than a threshold voltage.

16. The method of claim 10, wherein detecting an overshoot event comprises detecting when a voltage level of an input signal of the power amplifier is less than a threshold voltage.

17. A device, comprising:
means for detecting a tracking voltage overshoot event of a power amplifier; and
means for coupling an inductor coupled to a supply port of the power amplifier to a ground voltage during the tracking voltage overshoot event.

18. The device of claim 17, further comprising means for pre-distorting an input signal of the power amplifier coupled to the means for detecting.

19. The device of claim 18, the means for pre-distorting configured to pre-distort the input signal based on a signal received from the means for detecting.

20. The device of claim 18, the means for pre-distorting configured to pre-distort the input signal based on feedback signal from an output of the power amplifier.
